(19) United States
(12) Patent Application Publication
(10) Pub. No.: US 2005/0017186 A1
(43) Pub. Date: Jan. 27, 2005

(54) Method and means for detecting internal larval infestation in granular material

(76) Inventor: Roy Emlyn Davies, Englefield Green (GB)

Correspondence Address: Andrew B Morton;Renner Kenner Greive Bobak Taylor & Weber, Fourth Floor, First National Tower, Akron, OH, 44308, US

(21) Appl. No.: 10/486,305

(22) PCT Filed: Jul. 26, 2002
(86) PCT No.: PCT/GB02/03538

(30) Foreign Application Priority Data
Jul. 27, 2001 (GB) 0118389.6

(51) Int. Cl. G01T 1/24; H01L 25/00

(52) U.S. Cl. 250/370.08

(57) ABSTRACT

A method for detecting internal larval infestation in granular material comprising the steps of: creating an image of grain kernels in the near Infra-Red region; applying a mask to the image to exclude interference on the outer reaches of the kernel; forming a model kernel by applying a medium filter and slightly enlarging the resulting approximate model; comparing the masked image with a model kernel to obtain a difference image; and applying a threshold to difference image to determine larval infestation.

The present invention relates to a method and means for detecting internal larval infestation in granular material such as grain kernels, eg cereal grain.

We have previously proposed a real time method and means for the rapid automatic detection of foreign object contaminants in cereals. This previous method is disclosed in GB97236 16.0 and the arrangement detects contaminants external to the grain kernels.

The problem of larval infestation in the grain kernels themselves is not addressed by the previous application.

The present invention provides a method and means for detecting infestation in grain kernels in which kernels are detected using near-infrared (NIR) radiation, preferably in the region of 981 nm.

In order that the present invention be more readily understood, an embodiment thereof will now be described with reference to the accompanying drawings, in which:

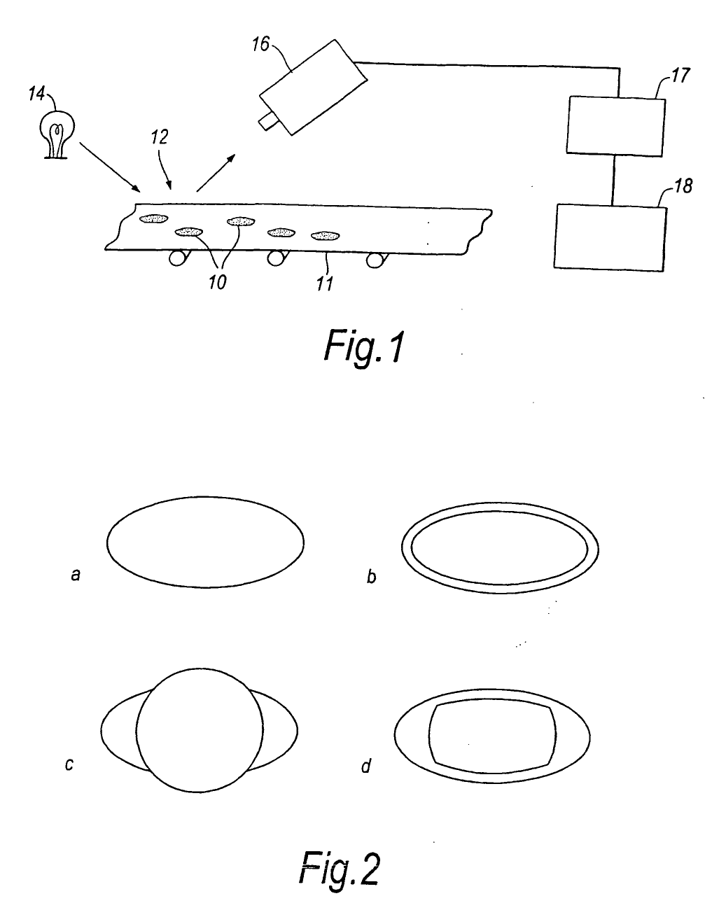

FIG. 1 shows diagrammatically apparatus for detecting internal larval infestation according to the present invention;

FIG. 2 shows the design of exclusion zone masks for use with the apparatus shown in FIG. 1;

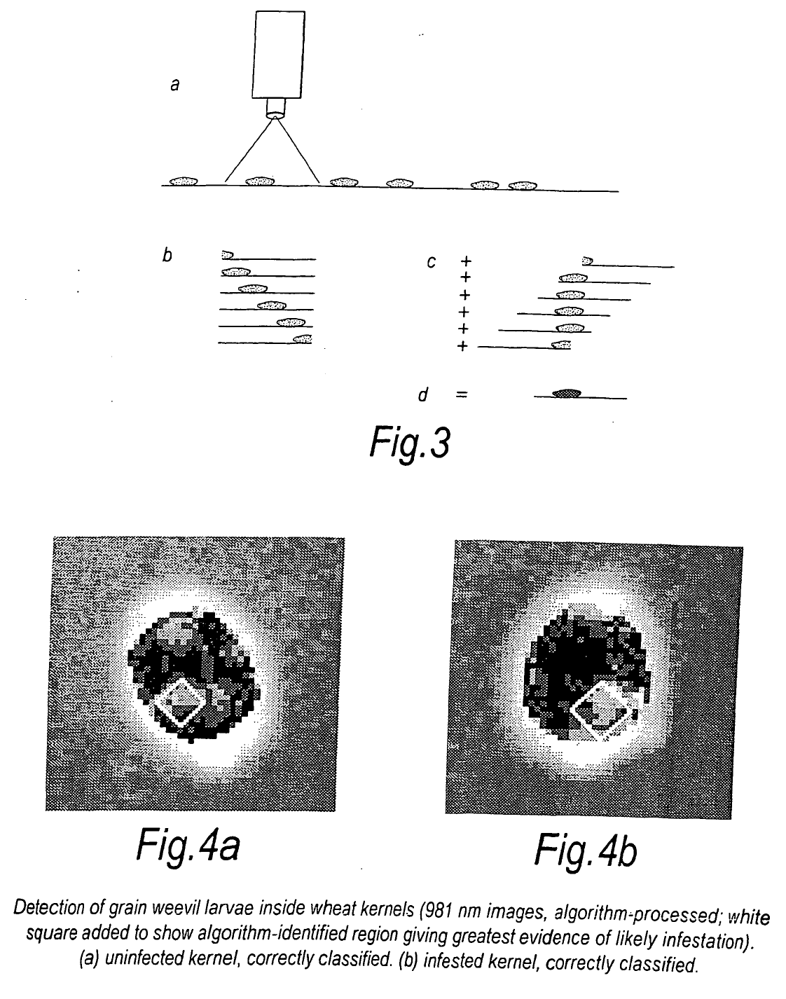

FIG. 3 shows diagrams to explain the use of an area camera as an enhanced line-scan camera; and

FIG. 4 shows uninfested and infested grain kernels after imaging and algorithm processing.

Grain kernels infested internally with developing stages of pest species such as S. granarius, for example, cannot be distinguished from uninfested kernels by visible inspection of their external appearance. A machine vision method has been devised capable of classifying wheat kernels as uninfested or containing S. granarius larvae based on differences in appearance when imaged at a specific wavelength in the NIR. A measurement wavelength (981 nm) has been identified from further, very near-infrared, spectroscopic studies of single uninfested and infested kernels where kernels infested with (large, late instar) larvae exhibit characteristic bright patching, thought to be a consequence of decreased absorption/increased scatter of NIR radiation due to starch loss as a result of insect feeding.

For imaging at 981 nm, the image capture set-up was very similar to that used for visible imaging as disclosed in GB97236 16.0. This was possible because the silicon detector-based CCD was sensitive into the NIR region up to around 1100 nm. To achieve wavelength selection, a narrow bandpass filter with central wavelength 981 nm was attached to the front of the camera lens. An array of standard household light bulbs was used to illuminate an infection area. The machine vision detection scheme was based on detection of the bright patching associated with internal infestation. Each grain kernel was compared with a model kernel and a difference image obtained. A mask was applied to exclude interference on the outer reaches of the kernel, and the most significant bright patches on the inner region were located. Finally, a threshold was applied to determine whether the bright patches corresponded to larval infestation, the threshold being set so as to maximise classification accuracy on the training set.

Turning now to FIG. 1, this shows a diagrammatic arrangement of apparatus according to the present invention.

Grain kernels 10 were placed in a vibratory conveyor 11 and passed through a monitoring zone 12 where they were illuminated with light from a light source 14. A video camera 16 having an image resolution of 256×256 pixels was positioned to view kernels in the monitoring zone 12 and produce monochrome 8 bit digital images. A bandpass filter with a central wavelength of 981 nm (bandwidth 9 nm at half height) was used so as to produce images from the camera at this wavelength.

The images from the camera 16 were captured using a frame grabber 17 and a plurality of frames were processed in an image processor 18 in order to improve the signal to noise ratio. Up to 100 frames could be used for this process but with improvements such as stronger illumination processing time can be reduced and only about 20-30 frames are required in order to produce meaningful results.

While the background for the images could be light or dark, it was found that a dark background allowed the boundaries of the grains to be more readily determined by computer.

The image processor 18 was then used to search for bright particles in the grain image. A model of grain intensities, by applying a suitable averaging filter to sample grain, was produced and any bright patches on the grain under test was revealed by simple differencing against the model. If the brightness is above a certain threshold, the grain is taken to be infested and otherwise it is taken to be uninfested.

In order to prevent edge effects introducing errors, each grain image was masked by a process represented by FIG. 2. First, a mask of constant width was engineered around but within the boundary of the grain. Second, the ends of the grain were excluded by further modifying the mask so that it would not extend outside a circular region centred at the centroid of the grain. The radius was determined as a factor beta times the radius of a circle of area equal to that of the grain being considered, beta being one of the parameters to be optimised for sensitivity.

The standard parameter adjustments need to be optimised for any new set of grain images. These parameters were:
1. The threshold value for initial detection of the grain against its dark background.
2. The amount by which the grain mask is shrunk to form the basic exclusion zone.
3. The radial distance parameter beta used in refining the exclusion zone.
4. The length of the filtering template used in generating the grain model.
5. The width of the filtering template used in generating the grain model.
6. The amount by which the grain size is expanded to help eliminate model boundary effects.
7. The threshold for truncation of the difference signal.
8. The multiplicative factor needed to maintain adequate precision in the patch brightness.
9. The bright patch size parameter.

All nine of these parameters were adjusted to optimise the classification accuracy (the percentage of kernels classified correctly whether uninfested or infested): all parameters were needed to guarantee the capability of optimisation, but the only way of optimising their values was to test for improvements in classification accuracy.

Two factors of importance arise from this in relation to the capture and processing of the images. One is that the objects on the conveyor have to remain relatively stationary during the acquisition period. However, they have to do so anyway over one object distance if their images are not to be distorted, so the need for them to remain relatively stationary for the necessary two object distances does not seem excessive. (The situation would be rendered more complicated if the objects are viewed in free fall, so this is not a preferred image acquisition mode).

The second factor is the need to synchronise the acquisition to the rate of progress of the conveyor, or vice versa—but this is a standard problem which applies for any line-scan camera acquisition system. A related factor is whether the images can be accumulated in real time at a sufficiently rapid rate. As additions are considerably less complicated than the image processing operations involved, this does not seem to be an insuperable problem. Indeed, we estimate that the break-even point will occur when about 30 lines are accumulated. When more than 30 lines have to be accumulated, dedicated DSP chips will provide an elegant way of solving the problem.

If one looks at FIG. 3, FIG. 3a shows the area camera grabbing an image; (b) shows a sequence of such images, taken as the conveyor moves to the right; (c) shows the various input images shifted so as to make the object appear stationary; and (d) shows the result of adding and averaging the input images, producing a final image of significantly increased SNR. Whereas each input image has limited length, the output image has essentially infinite length. The number of images added and averaged to produce each final image pixel is equal to the height of the original camera image (eg 100 or even 256), though smaller numbers in the range 20-30 pixels normally improve the SNR sufficiently.

The above description makes reference to an averaging filter that was applied to cut out the bright patches on the grains. It was found crucial to use a median filter for this purpose. In fact, this is counter-intuitive, as elimination of bright patches should have required the application of a local minimum filter, so that image subtraction would give the strongest possible signals for the bright patches. A median filter should not only have removed bright patches but also dark patches, thereby distorting the overall signal, and providing a misleading “modelled” background against which to locate the bright patches. However, for reasons which are not fully understood, this turned out not to be the case. In fact, many types of filter were tried in windows of all sizes and a variety of shapes. These included maximum filters, minimum filters, median filters, other sorts of rank-order filter, and mean filters. Median filters were considerably more effective than all the others, and unusually large filters had to be used. A further counter-intuitive fact was that the filters had to be rectangular for best response, with the long edge parallel to the main axis of each grain. Here there is an explanation in that the rectangular filters were best placed aligned long the image axes (along which the grains were also aligned in our experiments) as this helped to cut out remanent striations due to poor camera (or, more likely, frame grabber) performance during acquisition. This is not expected to be a feature of the type of camera to be used in a final implementation of the algorithm. Hence elliptical windows aligned along the grain direction are expected to be optimal and are the preferred implementation—with rectangular windows being preferable in any instance of camera striations appearing. The optimum size of the window is about half to one third of the dimension of the grain—a very large size. which a priori would have been expected to produce significant distortions.

The dark background is preferred, as the intensity pattern in the images then increases monotonically from the background towards the centre of the grain. This permits the modelling filter to cause minimal disruption of the grain profile in the absence of any bright patches.

Nevertheless, when the modelling filter is applied to the grain, it causes the object to shrink slightly. We compensate it by dilating the grain profile slightly. Because of the variation in curvature around the grain, the compensation is not perfect around the very outside of the grain, but its effect within the grain boundary is to restore the intensity profile to very nearly the profile of an ideal grain model, and this last property is of prime importance. The remaining shape distortion at the very edge of the object matters much less, as a mask is later applied to eliminate the boundary of the object from consideration.

Experiments were carried out on wheat grains and these showed two important factors. First, that the grain intensity profile modelling is less accurate at the boundaries of the grains, and also that relatively meaningless bright patches tended to occur in these regions (they are relatively meaningless as the larvae are sufficiently large that they are less likely to be close to the boundaries of the grain than in the middle, as indicated also by X-ray analysis). Hence it is beneficial to eliminate the grain boundaries from consideration—though the width of the region over which this applies has to be determined experimentally.

Second, the pointed ends of the grain seem to have different internal composition from the remainder of the grain, making them appear relatively bright. As a result they do not provide good indicators as to the presence of internal insect infestation. So again it is beneficial to eliminate these regions from consideration—and again the region over which this has to be applied has to be determined experimentally.

To design suitable exclusion masks for this purpose it seemed appropriate to choose masks that were easily specifiable and independent of grain orientation. On the other hand, the precise shape did not matter too much as there was too little evidence from grain samples to determine it exactly. So the first condition led to a uniform width of exclusion around the grain boundary (FIG. 2b) and the second condition led to a circular exclusion zone centred at the centroid of the shape. FIG. 2 shows the design concept and the overall shape of the final exclusion mask which is shown in FIG. 2d.

It is envisaged that if other species of grain have to be monitored, the same model will be appropriate, but the exact values of the two mask shape parameters will naturally have to be adjusted. It is believed that the total number of parameters in the model and elsewhere in the algorithm (specifically, there are nine of these) has been reduced to a working minimum which will be adaptable from the case of wheat to other grain species. The specific advantage of having a minimum number of parameters is that they can be reasonably accurately determined with a minimum of experimental data, and indeed their values will be statistically significant.

In summary, the overall process is:
a) Load the input grains onto a conveyor, with sparse spacing, using a vibratory feeder to ensure that they are mostly crease-side down.
b) Acquire images using area camera.
c) Average the input images on a staggered, line-by-line basis, to form original image I, as shown in FIG. 2.
d) Locate individual grains in I.
e) Create an area of interest around each grain to save later computation (optional).
f) Apply modelling (median) filter to I, giving I′ (optionally just around each grain).
g) Apply object dilation filter to I′ to form final grain model M.
h) Form difference image D (finds absolute differences between image I and model M).
i) Calculate exclusion zone Z, as shown in FIG. 1.
j) Determine support region excluding Z giving the maximum averaged response R to D.
k) Threshold R to give basic indication of numbers N of infested grains, and diverting these grains into a ‘probably infested’ output channel.
l) Threshold the number N to give a final judgment on batch infestation.
m) If the judgment is disputed, cut up the ‘probably infested’ grains and demonstrate that most of them are infested.

When carrying out the thresholding with N to give a final judgment on batch infestation, it is important to distinguish between two major types of error, namely false positives and false negatives. Generally, in food inspection apparatus one errs on the side of locating all the contaminants, even if this means that the number of false positives (ie the number of items that are wrongly interpreted as contaminants) is increased.

For batch analysis, we have concluded that it is better to ensure that fewer rather than more false positives occur so that when the rejected kernels from a batch are collected and examined, they will very obviously be ones containing larval infestation.

We therefore do not work to minimize false negatives, nor do we work to minimize total error (ie false positives plus false negatives), rather we move towards fewer false positives even if this results in slightly inflated numbers of false negatives.

We prefer to operate the apparatus in such a way that we can detect 1000 infested grains in a batch of 60,000 leading to 379 false alarms and 189 actual larvae found. In other words, one third of all positives that are collected are true positives and this is checked merely by cutting up a few grains.

Features of the invention which are of importance are:
1. The use of an area camera rather than a line-scan camera to permit multiple images to be gathered and averaged. The averaging is done in the computer or other hardware. The average intensity of the bright patch on a grain could be taken as the sole indicator of information on potential infestation, and all other information discarded. In any field dispute about the validity of this index of infestation, the grains would be cut open and the proportion of the grains found to be actually infested would be taken as the absolute indication of infestation. For this to be possible, the preferred implementation would not only assess the numbers of grains infested but would divert those deemed to be infested to a separate output channel.
2. The use of an optical high-wavelength pass filter rather than a band-pass filter (or otherwise a rather wide band-pass filter) to separate moisture from starch bands in the images.
3. The use of a water-jacket around the camera and water-cooling on the conveyor supports to prevent overheating from relatively strong illumination.
4. The use of a dark (at NIR wavelengths) background against which to view the cereal grains.
5. The use of grain models.
6. The comparison of individual grains with idealised models of themselves rather than with a general model produced by normalisation and averaging (which has been found to be ineffective).
7. The use of a median filter as the basic averaging filter that is applied to produce the ideal object model.
8. The use of a very large median filter in an elliptical window (or rectangular window aligned along the image axes directions in case of camera striations) as the basic modelling filter.
9. The use of a grey-scale object dilation filter after the modelling filter, to largely correct for the intensity profile distortions produced by the latter.
10. The use of a specially designed composite exclusion zone mask to eliminate regions of the cereal grains which are on balance likely to give misleading signals.
11. The use of a bright patch detection filter of wide support (ie containing a spatial averaging component) to detect bright patches corresponding to insect infestation, together with a means of characterising and locating the brightest of these patches, as indicating the strongest evidence for infestation.
12. The use of thresholding of the final maximum averaged difference intensity as the basic indicator of infestation.
13. The use of a further threshold on numbers of grains classified as infested as the final indicator of batch infestation.
14. The use of algorithms that are well-adapted to real-time processing so that they can be speeded up by straightforward means, whether in software or special low-cost hardware.

As a modification, the NIR imaging techniques disclosed above could be used to monitor granular material such as flour for the presence of infestation below the surface of the flour.

1. A method for detecting internal larval infestation in granular material comprising the steps of:
creating an image of grain kernels in the near Infra-Red region;
applying a mask to the image to exclude interference on the outer reaches of the kernel;
forming a model kernel by applying a median filter and slightly enlarging the resulting approximate model;
comparing the masked image with the model kernel to obtain a difference image; and
applying a threshold to difference image to determine larval infestation.

2. A method according to claim 1, wherein the model application step comprises applying a median filter to the grain image.

3. A method according to claim 1, wherein the grain image is created using a background which is darker than the grain at near Infra-Red wavelengths.

4. Apparatus for detecting internal larval infestation in granular material comprising:
means for creating an image of grain kernels in the near Infra-Red region;
masking means for masking the image to exclude interference on the outer reaches of the kernel;
a comparator for comparing the masked image with a model kernel to obtain a difference image; and
thresholding means for applying a threshold to the difference image to determine larval infestation.

5. Apparatus according to claim 4, wherein the masking means is associated with a median filter.

6. Apparatus according to claim 4, wherein the image creating means includes a background which is darker than the grain at near Infra-Red wavelengths.

7. Apparatus according to claim 4, and comprising further thresholding means for applying a further threshold in order to determine whether or not to accept a batch of grain.

8. Apparatus according to claim 7, wherein the further threshold means is arranged to reduce the number of false positives but not to eliminate them.

9. Apparatus according to claim 8, where threshold means is arranged to produce typically two false positives for every one true positive.
